(19) United States
(12) Patent Application Publication
(10) Pub. No.: US 2025/0385754 A1
(43) Pub. Date: Dec. 18, 2025

(54) CODE BLOCK (CB) CYCLIC REDUNDANCY CHECK (CRC) BITS INSERTION

(71) Applicant: QUALCOMM Incorporated, San Diego, CA (US)

(72) Inventors: Somsubhra BARIK, San Diego, CA (US); Jing SUN, San Diego, CA (US); Wei YANG, San Diego, CA (US); Jing JIANG, San Diego, CA (US)

(21) Appl. No.: 18/743,939

(22) Filed: Jun. 14, 2024

(51) Int. Cl. H04L 1/00; H03M 13/25

(52) U.S. Cl. CPC H04L 1/0061; H03M 13/255; H04L 1/0067

(57) ABSTRACT

Certain aspects of the present disclosure provide a method for wireless communications at a transmitter node. The transmitter node may append one or more cyclic redundancy check (CRC) bits at an end of one or more code block (CB) bundles. Each of the one or more CB bundles may include multiple CBs. The transmitter node may transmit at least one of the one or more CB bundles.

### BACKGROUND

### Field of the Disclosure

Aspects of the present disclosure relate to wireless communications, and more particularly, to techniques for managing cyclic redundancy check (CRC) bits for a transport block (TB).

### Description of Related Art

Wireless communications systems are widely deployed to provide various telecommunication services such as telephony, video, data, messaging, broadcasts, or other similar types of services. These wireless communications systems may employ multiple-access technologies capable of supporting communications with multiple users by sharing available wireless communications system resources with those users.

Although wireless communications systems have made great technological advancements over many years, challenges still exist. For example, complex and dynamic environments can still attenuate or block signals between wireless transmitters and wireless receivers. Accordingly, there is a continuous desire to improve the technical performance of wireless communications systems, including, for example: improving speed and data carrying capacity of communications, improving efficiency of the use of shared communications mediums, reducing power used by transmitters and receivers while performing communications, improving reliability of wireless communications, avoiding redundant transmissions and/or receptions and related processing, improving the coverage area of wireless communications, increasing the number and types of devices that can access wireless communications systems, increasing the ability for different types of devices to intercommunicate, increasing the number and type of wireless communications mediums available for use, and the like. Consequently, there exists a need for further improvements in wireless communications systems to overcome the aforementioned technical challenges and others.

### SUMMARY

One aspect provides a method for wireless communications at a transmitter node. The method includes appending one or more cyclic redundancy check (CRC) bits at an end of one or more code block (CB) bundles, wherein each of the one or more CB bundles comprises a plurality of CBs; and transmitting at least one of the one or more CB bundles.

Another aspect provides a method for wireless communications at a transmitter node. The method includes appending a first quantity of CRC bits at an end of at least one CB of a CB bundle comprising a plurality of CBs, wherein the first quantity of CRC bits is less than a second quantity of CRC bits configured for the at least one CB of the CB bundle; and transmitting the CB bundle.

Other aspects provide: an apparatus operable, configured, or otherwise adapted to perform the aforementioned methods as well as those described elsewhere herein; a non-transitory, computer-readable media comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and an apparatus comprising means for performing the aforementioned methods as well as those described elsewhere herein. By way of example, an apparatus may comprise a processing system, a device with a processing system, or processing systems cooperating over one or more networks.

The following description and the appended figures set forth certain features for purposes of illustration.

### BRIEF DESCRIPTION OF DRAWINGS

The appended figures depict certain features of the various aspects described herein and are not to be considered limiting of the scope of this disclosure.

FIG. 1 depicts an example wireless communications network.

FIG. 2 depicts an example disaggregated base station (BS) architecture.

FIG. 3 depicts aspects of an example BS and an example user equipment (UE).

FIG. 4A, FIG. 4B, FIG. 4C, and FIG. 4D depict various example aspects of data structures for a wireless communications network.

FIG. 5 depicts example data transport process.

FIG. 6 depicts a call flow diagram illustrating example communication among different wireless nodes for managing cyclic redundancy check (CRC) bits for a code blocks (CB) bundle.

FIG. 7 depicts example CRC bits at an end of a last CB of a CB bundle.

FIG. 8 depicts example bits in one or more CBs of a CB bundle.

FIG. 9 depicts example bits in a CB of a CB bundle and in a CB bundle CRC.

FIGS. 10 and 11 depict example methods for wireless communications at a transmitter node for managing CRC bits for a CB bundle.

FIG. 12 depicts example communications device for managing CRC bits for a CB bundle.

### DETAILED DESCRIPTION

Aspects of the present disclosure provide apparatuses, methods, processing systems, and computer-readable mediums for managing cyclic redundancy check (CRC) bits for a transport block (TB).

A CRC generally refers to a mechanism used to detect errors in a TB data transmission. For example, a CRC algorithm may generate a checksum, which is a fixed-size value derived from data being transmitted. This checksum is appended to the TB data and sent along with it to a receiver. Upon receiving the TB data, the receiver implements the same CRC algorithm and compares a calculated checksum with the received checksum. If they match, it indicates that the TB data was received correctly. Otherwise, it suggests that errors have occurred during the transmission or processing at the receiver side.

In some cases, to ensure efficient and reliable data transmission, a large TB may be divided into smaller segments (e.g., code blocks (CBs). For example, a single TB may be divided into multiple CBs. In such cases, a CRC (e.g., the checksum) may be calculated and attached to each CB of the TB. This may allow for error detection at the receiver on a per-CB basis. Currently, each CB of the TB may have 24 bits of CRC. For large TB sizes, a number of CBs for the TB may scale up easily and per CB CRCs may result in too much overall CRC overhead for the TB.

To reduce the CRC overhead for the TB, techniques described herein may group some CBs of the TB to form a CB bundle. The CBs within the CB bundle may experience a similar channel variation in a frequency domain, and are likely to be decoded at a same time. Therefore, for error detection, a CRC check for an individual CB of the TB can be avoided and instead a CRC check at a CB bundle-level may be performed. For example, CRC bits may be calculated and attached at an end of the CB bundle being transmitted, rather than at the end of each CB within the CB bundle. By using the CB bundle-level CRC (e.g., instead of the CB-level CRC), the described techniques may provide an overall resource saving and may help improve an overall data rate.

### Introduction to Wireless Communications Networks

The techniques and methods described herein may be used for various wireless communications networks. While aspects may be described herein using terminology commonly associated with 3G, 4G, and/or 5G wireless technologies, aspects of the present disclosure may likewise be applicable to other communications systems and standards not explicitly mentioned herein.

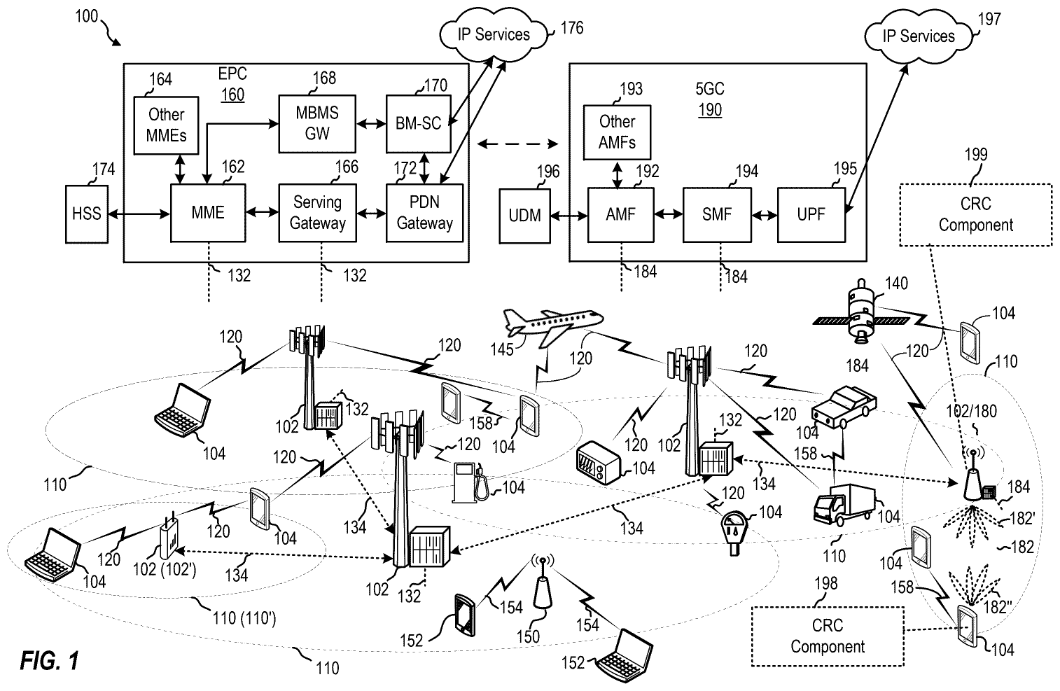

FIG. 1 depicts an example of a wireless communications network 100, in which aspects described herein may be implemented.

Generally, wireless communications network 100 includes various network entities (alternatively, network elements or network nodes). A network entity is generally a communications device and/or a communications function performed by a communications device (e.g., a user equipment (UE), a base station (BS), a component of a BS, a server, etc.). For example, various functions of a network as well as various devices associated with and interacting with a network may be considered network entities. Further, wireless communications network 100 includes terrestrial aspects, such as ground-based network entities (e.g., BSs 102), and non-terrestrial aspects, such as satellite 140 and aircraft 145, which may include network entities on-board (e.g., one or more BSs) capable of communicating with other network elements (e.g., terrestrial BSs) and UEs.

In the depicted example, wireless communications network 100 includes BSs 102, UEs 104, and one or more core networks, such as an Evolved Packet Core (EPC) 160 and 5G Core (5GC) network 190, which interoperate to provide communications services over various communications links, including wired and wireless links.

FIG. 1 depicts various example UEs 104, which may more generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. UEs 104 may also be referred to more generally as a mobile device, a wireless device, a wireless communications device, a station, a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and others.

BSs 102 wirelessly communicate with (e.g., transmit signals to or receive signals from) UEs 104 via communications links 120. The communications links 120 between BSs 102 and UEs 104 may include uplink (UL) (also referred to as reverse link) transmissions from a UE 104 to a BS 102 and/or downlink (DL) (also referred to as forward link) transmissions from a BS 102 to a UE 104. The communications links 120 may use multiple-input and multiple-output (MIMO) antenna technology, including spatial multiplexing, beamforming, and/or transmit diversity in various aspects.

BSs 102 may generally include: a NodeB, enhanced NodeB (eNB), next generation enhanced NodeB (ng-eNB), next generation NodeB (gNB or gNodeB), access point, base transceiver station, radio BS, radio transceiver, transceiver function, transmission reception point, and/or others. Each of BSs 102 may provide communications coverage for a respective geographic coverage area 110, which may sometimes be referred to as a cell, and which may overlap in some cases (e.g., small cell 102′ may have a coverage area 110′ that overlaps the coverage area 110 of a macro cell). A BS may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

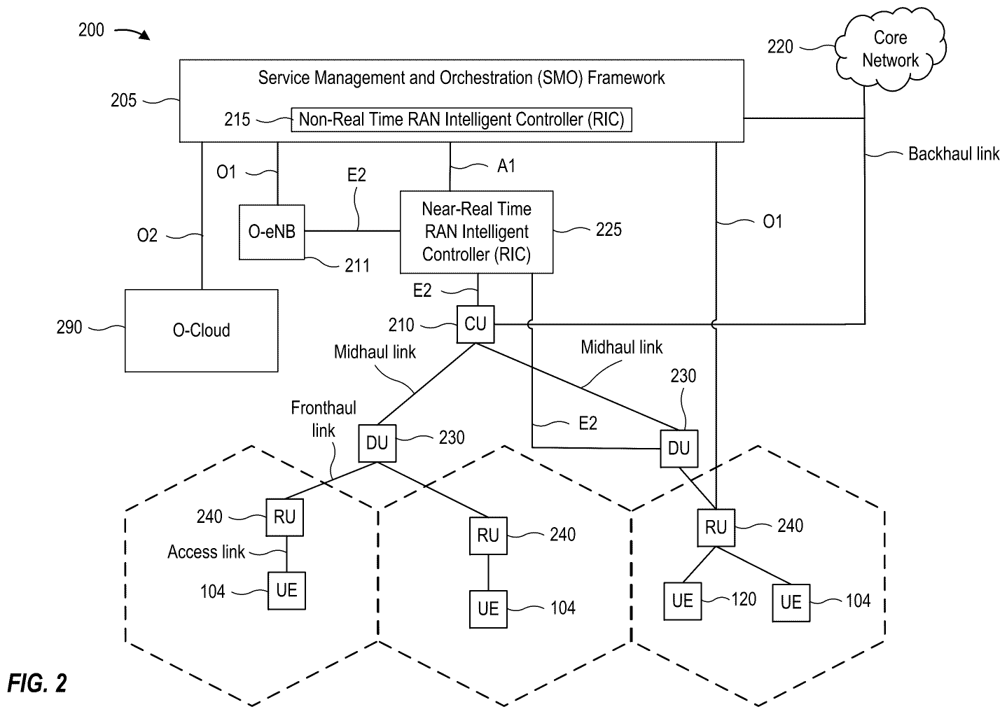

While BSs 102 are depicted in various aspects as unitary communications devices, BSs 102 may be implemented in various configurations. For example, one or more components of a BS 102 may be disaggregated, including a central unit (CU), one or more distributed units (DUs), one or more radio units (RUs), a Near-Real Time (Near-RT) RAN Intelligent Controller (RIC), or a Non-Real Time (Non-RT) RIC, to name a few examples. In another example, various aspects of a BS 102 may be virtualized. More generally, a BS (e.g., BS 102) may include components that are located at a single physical location or components located at various physical locations. In examples in which a BS 102 includes components that are located at various physical locations, the various components may each perform functions such that, collectively, the various components achieve functionality that is similar to a BS 102 that is located at a single physical location. In some aspects, a BS 102 including components that are located at various physical locations may be referred to as a disaggregated radio access network (RAN) architecture, such as an Open RAN (O-RAN) or Virtualized RAN (VRAN) architecture. FIG. 2 depicts and describes an example disaggregated BS architecture.

Different BSs 102 within wireless communications network 100 may also be configured to support different radio access technologies, such as 3G, 4G, and/or 5G. For example, BSs 102 configured for 4G LTE (collectively referred to as Evolved Universal Mobile Telecommunications System (UMTS) Terrestrial Radio Access Network (E-UTRAN)) may interface with the EPC 160 through first backhaul links 132 (e.g., an S1 interface). BSs 102 configured for 5G (e.g., 5G NR or Next Generation RAN (NG-RAN)) may interface with 5GC 190 through second backhaul links 184. BSs 102 may communicate directly or indirectly (e.g., through the EPC 160 or 5GC 190) with each other over third backhaul links 134 (e.g., X2 interface), which may be wired or wireless.

Wireless communications network 100 may subdivide the electromagnetic spectrum into various classes, bands, channels, or other features. In some aspects, the subdivision is provided based on wavelength and frequency, where frequency may also be referred to as a carrier, a subcarrier, a frequency channel, a tone, or a subband. For example, 3GPP currently defines Frequency Range 1 (FR1) as including 600 MHz-6 GHz, which is often referred to (interchangeably) as “Sub-6 GHz”. Similarly, 3GPP currently defines Frequency Range 2 (FR2) as including 26-41 GHz, which is sometimes referred to (interchangeably) as a “millimeter wave” (“mmW” or “mmWave”). A BS configured to communicate using mm Wave/near mm Wave radio frequency bands (e.g., a mmWave BS such as BS 180) may utilize beamforming (e.g., 182) with a UE (e.g., 104) to improve path loss and range.

The communications links 120 between BSs 102 and, for example, UEs 104, may be through one or more carriers, which may have different bandwidths (e.g., 5, 10, 15, 20, 100, 400, and/or other MHz), and which may be aggregated in various aspects. Carriers may or may not be adjacent to each other. Allocation of carriers may be asymmetric with respect to DL and UL (e.g., more or fewer carriers may be allocated for DL than for UL).

Communications using higher frequency bands may have higher path loss and a shorter range compared to lower frequency communications. Accordingly, certain BSs (e.g., 180 in FIG. 1) may utilize beamforming 182 with a UE 104 to improve path loss and range. For example, BS 180 and the UE 104 may each include a plurality of antennas, such as antenna elements, antenna panels, and/or antenna arrays to facilitate the beamforming. In some cases, BS 180 may transmit a beamformed signal to UE 104 in one or more transmit directions 182′. UE 104 may receive the beamformed signal from the BS 180 in one or more receive directions 182″. UE 104 may also transmit a beamformed signal to the BS 180 in one or more transmit directions 182″. BS 180 may also receive the beamformed signal from UE 104 in one or more receive directions 182′. BS 180 and UE 104 may then perform beam training to determine the best receive and transmit directions for each of BS 180 and UE 104. Notably, the transmit and receive directions for BS 180 may or may not be the same. Similarly, the transmit and receive directions for UE 104 may or may not be the same.

Wireless communications network 100 further includes a Wi-Fi AP 150 in communication with Wi-Fi stations (STAs) 152 via communications links 154 in, for example, a 2.4 GHz and/or 5 GHz unlicensed frequency spectrum.

Certain UEs 104 may communicate with each other using device-to-device (D2D) communications link 158. D2D communications link 158 may use one or more sidelink channels, such as a physical sidelink broadcast channel (PSBCH), a physical sidelink discovery channel (PSDCH), a physical sidelink shared channel (PSSCH), a physical sidelink control channel (PSCCH), and/or a physical sidelink feedback channel (PSFCH).

EPC 160 may include various functional components, including: a Mobility Management Entity (MME) 162, other MMEs 164, a Serving Gateway 166, a Multimedia Broadcast Multicast Service (MBMS) Gateway 168, a Broadcast Multicast Service Center (BM-SC) 170, and/or a Packet Data Network (PDN) Gateway 172, such as in the depicted example. MME 162 may be in communication with a Home Subscriber Server (HSS) 174. MME 162 is the control node that processes the signaling between the UEs 104 and the EPC 160. Generally, MME 162 provides bearer and connection management.

Generally, user Internet protocol (IP) packets are transferred through Serving Gateway 166, which itself is connected to PDN Gateway 172. PDN Gateway 172 provides UE IP address allocation as well as other functions. PDN Gateway 172 and the BM-SC 170 are connected to IP Services 176, which may include, for example, the Internet, an intranet, an IP Multimedia Subsystem (IMS), a Packet Switched (PS) streaming service, and/or other IP services.

BM-SC 170 may provide functions for MBMS user service provisioning and delivery. BM-SC 170 may serve as an entry point for content provider MBMS transmission, may be used to authorize and initiate MBMS Bearer Services within a public land mobile network (PLMN), and/or may be used to schedule MBMS transmissions. MBMS Gateway 168 may be used to distribute MBMS traffic to the BSs 102 belonging to a Multicast Broadcast Single Frequency Network (MBSFN) area broadcasting a particular service, and/or may be responsible for session management (start/stop) and for collecting eMBMS related charging information.

5GC 190 may include various functional components, including: an Access and Mobility Management Function (AMF) 192, other AMFs 193, a Session Management Function (SMF) 194, and a User Plane Function (UPF) 195. AMF 192 may be in communication with Unified Data Management (UDM) 196.

AMF 192 is a control node that processes signaling between UEs 104 and 5GC 190. AMF 192 provides, for example, quality of service (QOS) flow and session management.

Internet protocol (IP) packets are transferred through UPF 195, which is connected to the IP Services 197, and which provides UE IP address allocation as well as other functions for 5GC 190. IP Services 197 may include, for example, the Internet, an intranet, an IMS, a PS streaming service, and/or other IP services.

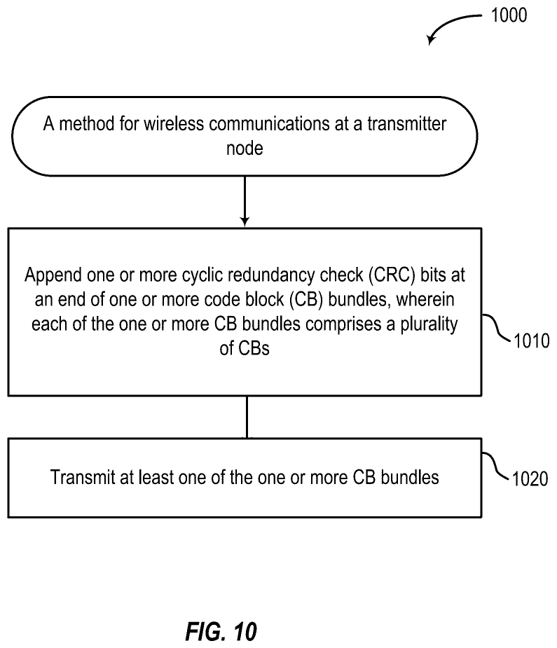

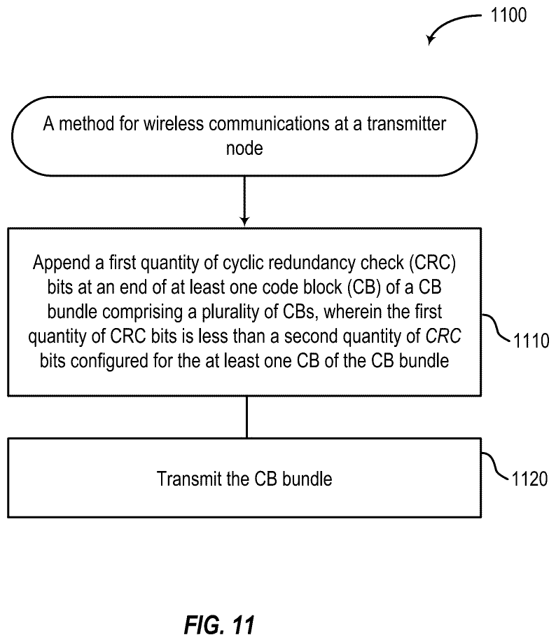

Wireless communication network 100 further includes cyclic redundancy check (CRC) component 198, which may be configured to perform method 1000 of FIG. 10 and/or method 1100 of FIG. 11. Wireless communication network 100 further includes CRC component 199, which may be configured to perform method 1000 of FIG. 10 and/or method 1100 of FIG. 11.

In various aspects, a network entity or network node can be implemented as an aggregated BS, as a disaggregated BS, a component of a BS, an integrated access and backhaul (IAB) node, a relay node, a sidelink node, to name a few examples.

FIG. 2 depicts an example disaggregated BS 200 architecture. The disaggregated BS 200 architecture may include one or more central units (CUs) 210 that can communicate directly with a core network 220 via a backhaul link, or indirectly with the core network 220 through one or more disaggregated BS units (such as a Near-Real Time (Near-RT) RAN Intelligent Controller (RIC) 225 via an E2 link, or a Non-Real Time (Non-RT) RIC 215 associated with a Service Management and Orchestration (SMO) Framework 205, or both). A CU 210 may communicate with one or more distributed units (DUs) 230 via respective midhaul links, such as an F1 interface. The DUs 230 may communicate with one or more radio units (RUs) 240 via respective fronthaul links. The RUs 240 may communicate with respective UEs 104 via one or more radio frequency (RF) access links. In some implementations, the UE 104 may be simultaneously served by multiple RUs 240.

Each of the units, e.g., the CUS 210, the DUs 230, the RUs 240, as well as the Near-RT RICs 225, the Non-RT RICs 215 and the SMO Framework 245, may include one or more interfaces or be coupled to one or more interfaces configured to receive or transmit signals, data, or information (collectively, signals) via a wired or wireless transmission medium. Each of the units, or an associated processor or controller providing instructions to the communications interfaces of the units, can be configured to communicate with one or more of the other units via the transmission medium. For example, the units can include a wired interface configured to receive or transmit signals over a wired transmission medium to one or more of the other units. Additionally or alternatively, the units can include a wireless interface, which may include a receiver, a transmitter or transceiver (such as a radio frequency (RF) transceiver), configured to receive or transmit signals, or both, over a wireless transmission medium to one or more of the other units.

In some aspects, the CU 210 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 210. The CU 210 may be configured to handle user plane functionality (e.g., Central Unit-User Plane (CU-UP)), control plane functionality (e.g., Central Unit-Control Plane (CU-CP)), or a combination thereof. In some implementations, the CU 210 can be logically split into one or more CU-UP units and one or more CU-CP units. The CU-UP unit can communicate bidirectionally with the CU-CP unit via an interface, such as the El interface when implemented in an O-RAN configuration. The CU 210 can be implemented to communicate with the DU 230, as necessary, for network control and signaling.

The DU 230 may correspond to a logical unit that includes one or more BS functions to control the operation of one or more RUs 240. In some aspects, the DU 230 may host one or more of a radio link control (RLC) layer, a medium access control (MAC) layer, and one or more high physical (PHY) layers (such as modules for forward error correction (FEC) encoding and decoding, scrambling, modulation and demodulation, or the like) depending, at least in part, on a functional split, such as those defined by the 3rd Generation Partnership Project (3GPP). In some aspects, the DU 230 may further host one or more low PHY layers. Each layer (or module) can be implemented with an interface configured to communicate signals with other layers (and modules) hosted by the DU 230, or with the control functions hosted by the CU 210.

Lower-layer functionality can be implemented by one or more RUs 240. In some deployments, an RU 240, controlled by a DU 230, may correspond to a logical node that hosts RF processing functions, or low-PHY layer functions (such as performing fast Fourier transform (FFT), inverse FFT (IFFT), digital beamforming, physical random access channel (PRACH) extraction and filtering, or the like), or both, based at least in part on the functional split, such as a lower layer functional split. In such an architecture, the RU(s) 240 can be implemented to handle over the air (OTA) communications with one or more UEs 104. In some implementations, real-time and non-real-time aspects of control and user plane communications with the RU(s) 240 can be controlled by the corresponding DU 230. In some scenarios, this configuration can enable the DU(s) 230 and the CU 210 to be implemented in a cloud-based RAN architecture, such as a vRAN architecture.

The SMO Framework 205 may be configured to support RAN deployment and provisioning of non-virtualized and virtualized network elements. For non-virtualized network elements, the SMO Framework 205 may be configured to support the deployment of dedicated physical resources for RAN coverage requirements which may be managed via an operations and maintenance interface (such as an O1 interface). For virtualized network elements, the SMO Framework 205 may be configured to interact with a cloud computing platform (such as an open cloud (O-Cloud) 290) to perform network element life cycle management (such as to instantiate virtualized network elements) via a cloud computing platform interface (such as an O2 interface). Such virtualized network elements can include, but are not limited to, CUs 210, DUs 230, RUS 240 and Near-RT RICs 225. In some implementations, the SMO Framework 205 can communicate with a hardware aspect of a 4G RAN, such as an open eNB (O-eNB) 211, via an O1 interface. Additionally, in some implementations, the SMO Framework 205 can communicate directly with one or more RUs 240 via an O1 interface. The SMO Framework 205 also may include a Non-RT RIC 215 configured to support functionality of the SMO Framework 205.

The Non-RT RIC 215 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 225. The Non-RT RIC 215 may be coupled to or communicate with (such as via an A1 interface) the Near-RT RIC 225. The Near-RT RIC 225 may be configured to include a logical function that enables near-real-time control and optimization of RAN elements and resources via data collection and actions over an interface (such as via an E2 interface) connecting one or more CUs 210, one or more DUs 230, or both, as well as an O-eNB, with the Near-RT RIC 225.

In some implementations, to generate AI/ML models to be deployed in the Near-RT RIC 225, the Non-RT RIC 215 may receive parameters or external enrichment information from external servers. Such information may be utilized by the Near-RT RIC 225 and may be received at the SMO Framework 205 or the Non-RT RIC 215 from non-network data sources or from network functions. In some examples, the Non-RT RIC 215 or the Near-RT RIC 225 may be configured to tune RAN behavior or performance. For example, the Non-RT RIC 215 may monitor long-term trends and patterns for performance and employ AI/ML models to perform corrective actions through the SMO Framework 205 (such as reconfiguration via O1) or via creation of RAN management policies (such as A1 policies).

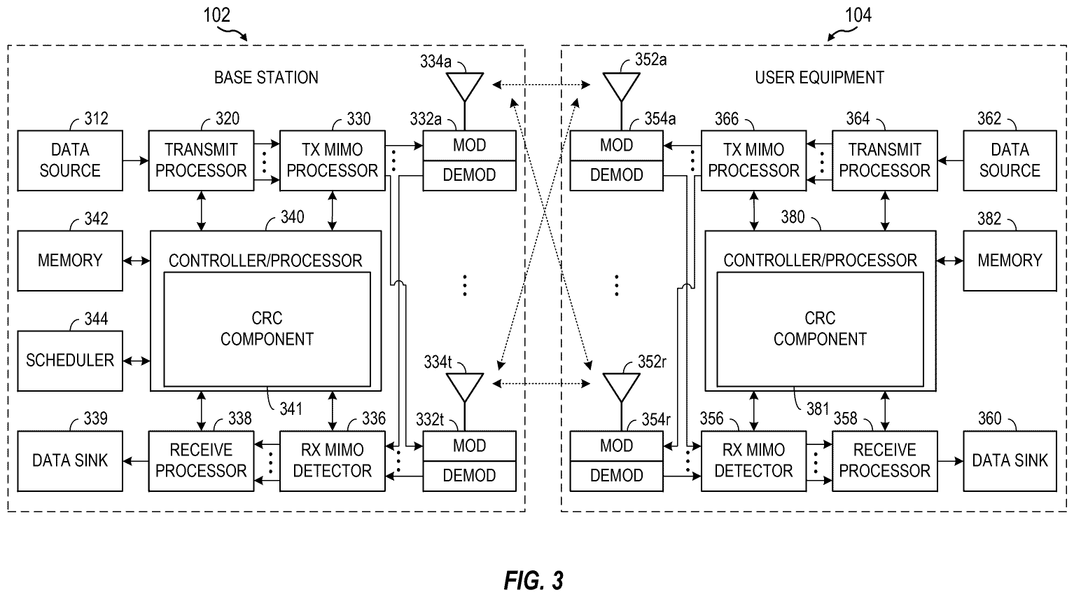

FIG. 3 depicts aspects of an example BS 102 and a UE 104.

Generally, BS 102 includes various processors (e.g., 324, 330, 338, and 340), antennas 334a-t (collectively 334), transceivers 332a-t (collectively 332), which include modulators and demodulators, and other aspects, which enable wireless transmission of data (e.g., data source 312) and wireless reception of data (e.g., data sink 339). For example, BS 102 may send and receive data between BS 102 and UE 104. BS 102 includes controller/processor 340, which may be configured to implement various functions described herein related to wireless communications.

BS 102 includes controller/processor 340, which may be configured to implement various functions related to wireless communications. In the depicted example, controller/processor 340 includes CRC component 341, which may be representative of CRC component 199 of FIG. 1. Notably, while depicted as an aspect of controller/processor 340, CRC component 341 may be implemented additionally or alternatively in various other aspects of BS 102 in other implementations.

Generally, UE 104 includes various processors (e.g., 358, 364, 366, and 380), antennas 352a-r (collectively 352), transceivers 354a-r (collectively 354), which include modulators and demodulators, and other aspects, which enable wireless transmission of data (e.g., retrieved from data source 362) and wireless reception of data (e.g., provided to data sink 360). UE 104 includes controller/processor 380, which may be configured to implement various functions described herein related to wireless communications.

UE 104 includes controller/processor 380, which may be configured to implement various functions related to wireless communications. In the depicted example, controller/processor 380 includes CRC component 381, which may be representative of CRC component 138 of FIG. 1. Notably, while depicted as an aspect of controller/processor 380, CRC component 381 may be implemented additionally or alternatively in various other aspects of UE 104 in other implementations.

In regards to an example downlink transmission, BS 102 includes a transmit processor 320 that may receive data from a data source 312 and control information from a controller/processor 340. The control information may be for the physical broadcast channel (PBCH), physical control format indicator channel (PCFICH), physical HARQ indicator channel (PHICH), physical downlink control channel (PDCCH), group common PDCCH (GC PDCCH), and/or others. The data may be for the physical downlink shared channel (PDSCH), in some examples.

Transmit processor 320 may process (e.g., encode and symbol map) the data and control information to obtain data symbols and control symbols, respectively. Transmit processor 320 may also generate reference symbols, such as for the primary synchronization signal (PSS), secondary synchronization signal (SSS), PBCH demodulation reference signal (DMRS), and channel state information reference signal (CSI-RS).

Transmit (TX) multiple-input multiple-output (MIMO) processor 330 may perform spatial processing (e.g., precoding) on the data symbols, the control symbols, and/or the reference symbols, if applicable, and may provide output symbol streams to the modulators (MODs) in transceivers 332a-332t. Each modulator in transceivers 332a-332t may process a respective output symbol stream to obtain an output sample stream. Each modulator may further process (e.g., convert to analog, amplify, filter, and upconvert) the output sample stream to obtain a downlink signal. Downlink signals from the modulators in transceivers 332a-332t may be transmitted via the antennas 334a-334t, respectively.

In order to receive the downlink transmission, UE 104 includes antennas 352a-352r that may receive the downlink signals from the BS 102 and may provide received signals to the demodulators (DEMODs) in transceivers 354a-354r, respectively. Each demodulator in transceivers 354a-354r may condition (e.g., filter, amplify, downconvert, and digitize) a respective received signal to obtain input samples. Each demodulator may further process the input samples to obtain received symbols.

MIMO detector 356 may obtain received symbols from all the demodulators in transceivers 354a-354r, perform MIMO detection on the received symbols if applicable, and provide detected symbols. Receive processor 358 may process (e.g., demodulate, deinterleave, and decode) the detected symbols, provide decoded data for the UE 104 to a data sink 360, and provide decoded control information to a controller/processor 380.

In regards to an example uplink transmission, UE 104 further includes a transmit processor 364 that may receive and process data (e.g., for the PUSCH) from a data source 362 and control information (e.g., for the physical uplink control channel (PUCCH)) from the controller/processor 380. Transmit processor 364 may also generate reference symbols for a reference signal (e.g., for the SRS). The symbols from the transmit processor 364 may be precoded by a TX MIMO processor 366 if applicable, further processed by the modulators in transceivers 354a-354r (e.g., for SC-FDM), and transmitted to BS 102.

At BS 102, the uplink signals from UE 104 may be received by antennas 334a-t, processed by the demodulators in transceivers 332a-332t, detected by a MIMO detector 336 if applicable, and further processed by a receive processor 338 to obtain decoded data and control information sent by UE 104. Receive processor 338 may provide the decoded data to a data sink 339 and the decoded control information to the controller/processor 340.

Memories 342 and 382 may store data and program codes for BS 102 and UE 104, respectively.

Scheduler 344 may schedule UEs 104 for data transmission on the downlink and/or uplink.

In various aspects, BS 102 may be described as transmitting and receiving various types of data associated with the methods described herein. In these contexts, “transmitting” may refer to various mechanisms of providing or outputting data, such as outputting data from data source 312, scheduler 344, memory 342, transmit processor 320, controller/processor 340, TX MIMO processor 330, transceivers 332a-t, antenna 334a-t, and/or other aspects described herein. Similarly, “receiving” may refer to various mechanisms of obtaining data, such as obtaining data from antennas 334a-t, transceivers 332a-t, RX MIMO detector 336, controller/processor 340, receive processor 338, scheduler 344, memory 342, and/or other aspects described herein.

In various aspects, UE 104 may likewise be described as transmitting and receiving various types of data associated with the methods described herein. In these contexts, “transmitting” may refer to various mechanisms of outputting data, such as outputting data from data source 362, memory 382, transmit processor 364, controller/processor 380, TX MIMO processor 366, transceivers 354a-t, antenna 352a-t, and/or other aspects described herein. Similarly, “receiving” may refer to various mechanisms of obtaining data, such as obtaining data from antennas 352a-t, transceivers 354a-t, RX MIMO detector 356, controller/processor 380, receive processor 358, memory 382, and/or other aspects described herein.

In some aspects, a processor may be configured to perform various operations, such as those associated with the methods described herein, and transmit (output) to or receive (obtain) data from another interface that is configured to transmit or receive, respectively, the data.

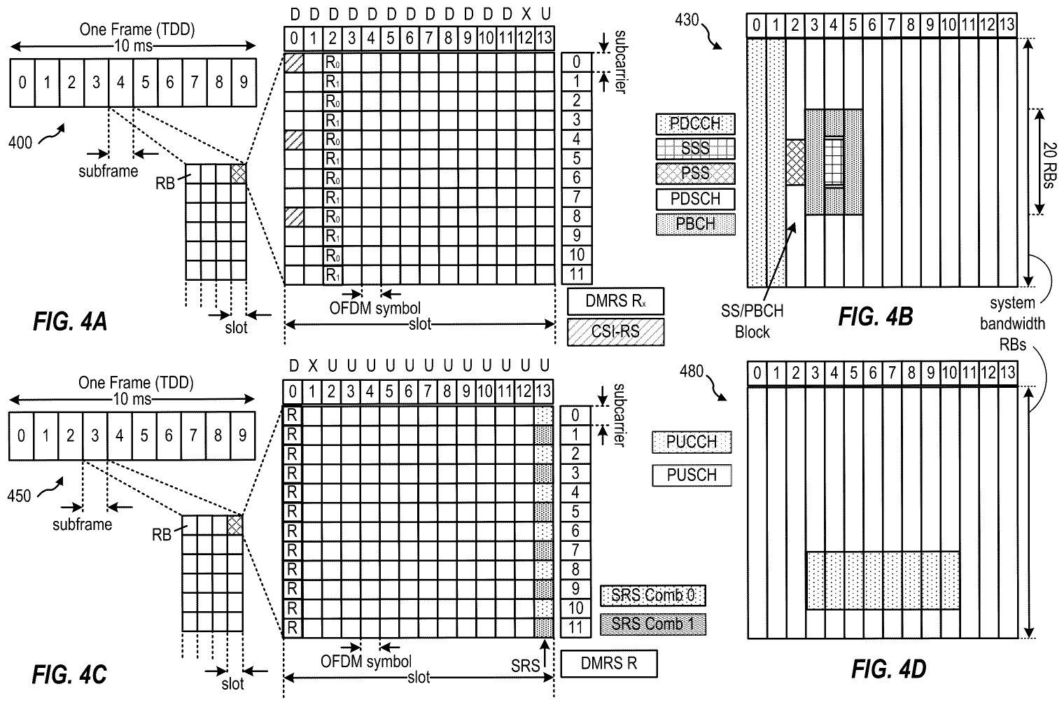

FIG. 4A, FIG. 4B, FIG. 4C, and FIG. 4D depict aspects of data structures for a wireless communications network, such as wireless communications network 100 of FIG. 1.

In particular, FIG. 4A is a diagram 400 illustrating an example of a first subframe within a 5G (e.g., 5G NR) frame structure, FIG. 4B is a diagram 430 illustrating an example of DL channels within a 5G subframe, FIG. 4C is a diagram 450 illustrating an example of a second subframe within a 5G frame structure, and FIG. 4D is a diagram 480 illustrating an example of UL channels within a 5G subframe.

Wireless communications systems may utilize orthogonal frequency division multiplexing (OFDM) with a cyclic prefix (CP) on the uplink and downlink. Such systems may also support half-duplex operation using time division duplexing (TDD). OFDM and single-carrier frequency division multiplexing (SC-FDM) partition the system bandwidth (e.g., as depicted in FIG. 4B and FIG. 4D) into multiple orthogonal subcarriers. Each subcarrier may be modulated with data. Modulation symbols may be sent in the frequency domain with OFDM and/or in the time domain with SC-FDM.

A wireless communications frame structure may be frequency division duplex (FDD), in which, for a particular set of subcarriers, subframes within the set of subcarriers are dedicated for either DL or UL. Wireless communications frame structures may also be TDD, in which, for a particular set of subcarriers, subframes within the set of subcarriers are dedicated for both DL and UL.

In FIG. 4A and 4C, the wireless communications frame structure is TDD where D is DL, U is UL, and X is flexible for use between DL/UL. UEs 104 may be configured with a slot format through a received slot format indicator (SFI) (dynamically through DL control information (DCI), or semi-statically/statically through radio resource control (RRC) signaling). In the depicted examples, a 10 ms frame is divided into 10 equally sized 1 ms subframes. Each subframe may include one or more time slots. In some examples, each slot may include 7 or 14 symbols, depending on the slot format. Subframes may also include mini-slots, which generally have fewer symbols than an entire slot. Other wireless communications technologies may have a different frame structure and/or different channels.

In certain aspects, the number of slots within a subframe is based on a slot configuration and a numerology. For example, for slot configuration 0, different numerologies (μ) 0 to 5 allow for 1, 2, 4, 8, 16, and 32 slots, respectively, per subframe. For slot configuration 1, different numerologies 0 to 2 allow for 2, 4, and 8 slots, respectively, per subframe. Accordingly, for slot configuration 0 and numerology μ, there are 14 symbols/slot and 2 slots/subframe. The subcarrier spacing and symbol length/duration are a function of the numerology. The subcarrier spacing may be equal to 2^{μ}×15 kHz, where u is the numerology 0 to 5. As such, the numerology μ=0 has a subcarrier spacing of 15 kHz and the numerology μ=5 has a subcarrier spacing of 480 kHz. The symbol length/duration is inversely related to the subcarrier spacing. FIG. 4A, FIG. 4B, FIG. 4C, and FIG. 4D provide an example of slot configuration 0 with 14 symbols per slot and numerology μ=2 with 4 slots per subframe. The slot duration is 0.25 ms, the subcarrier spacing is 60 kHz, and the symbol duration is approximately 16.67 μs.

As depicted in FIG. 4A, FIG. 4B, FIG. 4C, and FIG. 4D, a resource grid may be used to represent the frame structure. Each time slot includes a resource block (RB) (also referred to as physical RBs (PRBs)) that extends, for example, 12 consecutive subcarriers. The resource grid is divided into multiple resource elements (REs). The number of bits carried by each RE depends on the modulation scheme.

As illustrated in FIG. 4A, some of the REs carry reference (pilot) signals (RS) for a UE (e.g., UE 104 of FIG. 1 and FIG. 3). The RS may include demodulation RS (DMRS) and/or channel state information reference signals (CSI-RS) for channel estimation at the UE. The RS may also include beam measurement RS (BRS), beam refinement RS (BRRS), and/or phase tracking RS (PT-RS).

FIG. 4B illustrates an example of various DL channels within a subframe of a frame. The physical downlink control channel (PDCCH) carries DCI within one or more control channel elements (CCEs), each CCE including, for example, nine RE groups (REGs), each REG including, for example, four consecutive REs in an OFDM symbol.

A primary synchronization signal (PSS) may be within symbol 2 of particular subframes of a frame. The PSS is used by a UE (e.g., 104 of FIG. 1 and FIG. 3) to determine subframe/symbol timing and a physical layer identity.

A secondary synchronization signal (SSS) may be within symbol 4 of particular subframes of a frame. The SSS is used by a UE to determine a physical layer cell identity group number and radio frame timing.

Based on the physical layer identity and the physical layer cell identity group number, the UE can determine a physical cell identifier (PCI). Based on the PCI, the UE can determine the locations of the aforementioned DMRS. The physical broadcast channel (PBCH), which carries a master information block (MIB), may be logically grouped with the PSS and SSS to form a synchronization signal (SS)/PBCH block. The MIB provides a number of RBs in the system bandwidth and a system frame number (SFN). The physical downlink shared channel (PDSCH) carries user data, broadcast system information not transmitted through the PBCH such as system information blocks (SIBs), and/or paging messages.

As illustrated in FIG. 4C, some of the REs carry DMRS (indicated as R for one particular configuration, but other DMRS configurations are possible) for channel estimation at the BS. The UE may transmit DMRS for the PUCCH and DMRS for the PUSCH. The PUSCH DMRS may be transmitted, for example, in the first one or two symbols of the PUSCH. The PUCCH DMRS may be transmitted in different configurations depending on whether short or long PUCCHs are transmitted and depending on the particular PUCCH format used. UE 104 may transmit sounding reference signals (SRS). The SRS may be transmitted, for example, in the last symbol of a subframe. The SRS may have a comb structure, and a UE may transmit SRS on one of the combs. The SRS may be used by a BS for channel quality estimation to enable frequency-dependent scheduling on the UL.

FIG. 4D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and HARQ ACK/NACK feedback. The PUSCH carries data, and may additionally be used to carry a buffer status report (BSR), a power headroom report (PHR), and/or UCI.

### Introduction to mmWave Wireless Communications

In wireless communications, an electromagnetic spectrum is often subdivided into various classes, bands, channels, or other features. The subdivision is often provided based on wavelength and frequency, where frequency may also be referred to as a carrier, a subcarrier, a frequency channel, a tone, or a subband.

5^{th} generation (5G) networks may utilize several frequency ranges, which in some cases are defined by a standard, such as 3^{rd} generation partnership project (3GPP) standards. For example, 3GPP technical standard TS 38.101 currently defines Frequency Range 1 (FR1) as including 600 MHz-6 GHz, though specific uplink and downlink allocations may fall outside of this general range. Thus, FR1 is often referred to (interchangeably) as a “Sub-6 GHz” band.

Similarly, TS 38.101 currently defines Frequency Range 2 (FR2) as including 26-41 GHz, though again specific uplink and downlink allocations may fall outside of this general range. FR2, is sometimes referred to (interchangeably) as a “millimeter wave” (“mmW” or “mmWave”) band, despite being different from the extremely high frequency (EHF) band (30 GHz-300 GHz) that is identified by the International Telecommunications Union (ITU) as a “millimeter wave” band because wavelengths at these frequencies are between 1 millimeter and 10 millimeters.

Communications using mm Wave/near mm Wave radio frequency band (e.g., 3 GHz-300 GHz) may have higher path loss and a shorter range compared to lower frequency communications. As described above with respect to FIG. 1, a base station (BS) (e.g., 180) configured to communicate using mmWave/near mmWave radio frequency bands may utilize beamforming (e.g., 182) with a user equipment (UE) (e.g., 104) to improve path loss and range.

### Overview of Cyclic Redundancy Check (CRC)

A cyclic redundancy check (CRC) is designed to detect errors in data and information transmitted over a network. The CRC is performed by performing a binary solution on transmitted data at a sender's side and verifying the same at a receiver's side.

For example, the CRC is an algorithm used to detect errors in a data transmission. The CRC algorithm generates a checksum, which is a fixed-size value derived from the data being transmitted. This checksum is then appended to the data and sent along with it. Upon receiving the data, the receiver performs the same CRC algorithm and compares the calculated checksum with the received one. If they match, it indicates that the data was transmitted correctly. Otherwise, it suggests that errors have occurred during transmission.

The term CRC is used to describe this error-detecting method because check represents the “data verification,” redundancy refers to the “recheck method,” and cyclic points to the “algorithmic formula.”

In some cases, the CRC works by treating the data as a binary polynomial. The data is divided by a predefined divisor, known as the generator polynomial. The remainder of this division is the CRC checksum. To verify the integrity of the data, the receiver performs the same division operation. If the remainder is zero, the data is considered error-free. If the remainder is non-zero, it means that errors were detected in the data.

The CRC has several advantages when it comes to error detection in the data transmission. Firstly, it is simple and fast to calculate, making it suitable for real-time applications. Secondly, it can detect both random and burst errors, ensuring high reliability. Additionally, the CRC can detect a wide range of error patterns, providing robust error checking capabilities.

### Overview of Data Transport Process

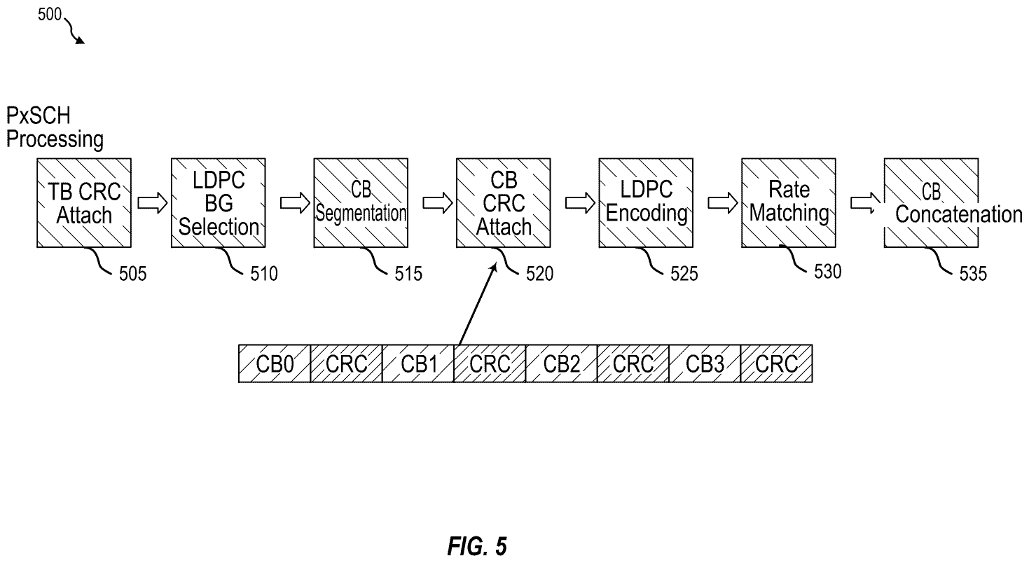

As illustrated in a diagram 500 of FIG. 5, at 505, a cyclic redundancy check (CRC) may be attached to a transport block (TB). For example, physical downlink shared channel (PDSCH) data may undergo a CRC attachment process to detect errors at a receiver. The TB CRC attachment in a PDSCH processing is a step that allows a user equipment (UE) to detect errors in a received TB from a gNodeB (gNB), and thereby ensuring a reliable data transmission over a wireless channel. The CRC may be calculated for the TB to enable an error detection at the receiver (e.g., the UE). The CRC may be a fixed-size checksum generated by applying a polynomial function to data of the TB. A 24-bit or a 16-bit CRC may be attached to the TB depending on a size of the TB.

At 510, after CRC attachment, the data is processed through a low-density parity check (LDPC) encoding for error correction purposes. For example, a LDPC graph selection may enable efficient channel coding tailored to a TB size, ensuring reliable data transmission and optimized performance. There may be two base graphs for LDPC encoding, known as base graph 1 and base graph 2. Each base graph has a predefined size, with base graph 1 being larger than base graph 2. The selection of a base graph depends on a size of the TB being transmitted over the PDSCH.

At 515, to ensure efficient and reliable data transmission, a large TB may be divided into smaller segments (e.g., code blocks (CBs). For example, a single TB may be segmented or divided into multiple CBs. In some cases, some of these CBs may be combined or grouped to form a CB bundle. That is, the single TB may include one or more CB bundles and each CB bundle may include one or more CBs.

In such cases, error detection capabilities may be provided at a CB-level. For example, after segmentation of the TB, at 520, a CRC may be calculated and attached to each CB of the TB individually. The CRC allows for error detection at the receiver on a per-CB basis.

At 525, the CBs may be channel-coded to protect against errors during transmission. For example, a LDPC encoding process takes the segmented CBs (with attached CRC) as input and generates parity bits based on the chosen base graph and lifting factor. These parity bits are then appended to the original data bits, forming a codeword that is transmitted over the PDSCH.

At 530, the channel-coded data is adjusted (e.g., rate matching) to fit the available transmission bandwidth. The rate matching may be done to adapt an output data rate of a channel encoder (LDPC) to match available resources allocated for transmission in a time-frequency grid of the PDSCH.

At 535, the rate-matched CBs may be concatenated back into a single data stream for transmission.

Currently, a TB may have 16 or 24 bits of a CRC overhead, while each CB of the TB may have 24 bits of CRC each. For large TB sizes (e.g., especially at higher bandwidths and ranks), a number of CBs for the TB may scale up easily and per CB CRCs may result in too much overhead and an overall throughput rate loss.

In some cases, when the CBs are interleaved in the CB bundle, all CBs of the CB bundle may experience a similar channel variation in a frequency domain. For example, a correlation of channels seen by the CBs may depend on an overall channel selectivity and a granularity of interleaving (i.e., units of resource elements allocated to a member CB in each interleaving step).

In some cases, correlation among the CBs belonging to a same CB bundle may imply that these CBs are likely to be decoded or not at a same time. So, a CRC check for an individual CB (e.g., pass or fail decoding) can be avoided by doing a CRC check only at a CB bundle-level instead of a CB-level.

### Aspects Related to Code Block (CB) Cyclic Redundancy Check (CRC) Insertion

Aspects of the present disclosure provide apparatuses, methods, processing systems, and computer-readable mediums for managing cyclic redundancy check (CRC) bits for a code block (CB) bundle including multiple CBs. For example, for error detection, CRC bits may be calculated and attached at an end of the CB bundle instead at the end of each CB within the CB bundle. In some cases, instead of replacing a CB-level CRC altogether, a smaller length CRC may be attached at the end of each CB within the CB bundle.

Particular aspects of the subject matter described in this disclosure can be implemented to realize one or more of the following potential advantages. For instance, by deploying the CB bundle-level CRC (instead of the CB-level CRC), the described techniques may provide an overall resource saving in a CRC overhead and may help improve an overall data rate.

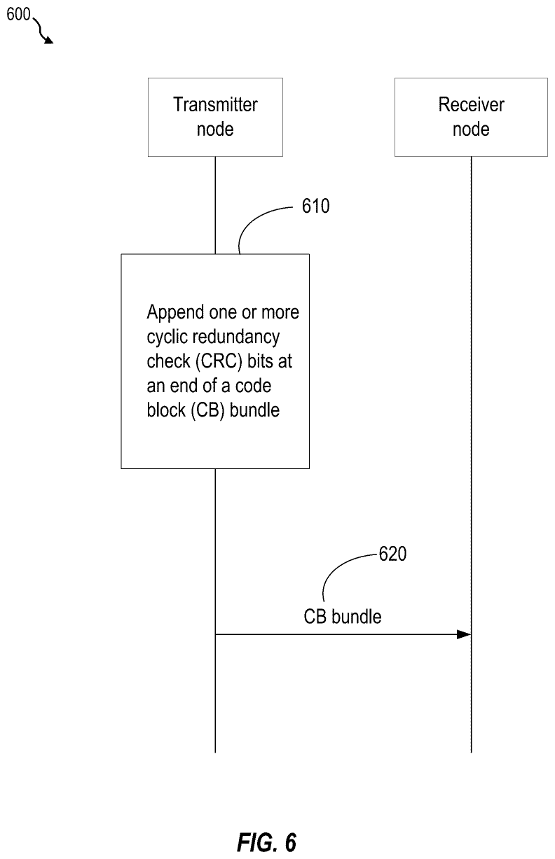

The techniques proposed herein for managing CRC bits for a CB bundle may be understood with reference to FIG. 6-FIG. 12.

FIG. 6 depicts a call flow diagram 600 illustrating example communication among wireless nodes (e.g., a transmitter node, a receiver node) for managing CRC bits for a CB bundle.

The transmitter node shown in FIG. 6 may be an example of the UE 104 depicted and described with respect to FIG. 1 and FIG. 3. In another example, the transmitter node depicted in FIG. 6 may be an example of the BS 102 depicted and described with respect to FIG. 1 and FIG. 3, or the disaggregated BS depicted and described with respect to FIG. 2.

The receiver node shown in FIG. 6 may be an example of the UE 104 depicted and described with respect to FIG. 1 and FIG. 3. In another example, the receiver node depicted in FIG. 6 may be an example of the BS 102 depicted and described with respect to FIG. 1 and FIG. 3, or the disaggregated BS depicted and described with respect to FIG. 2.

As indicated at 610, the transmitter node may append one or more CRC bits at an end of a CB bundle of a transport block (TB). In one example, the TB may include one CB bundle. In another example, the TB may include multiple CB bundles. The CB bundle may include one or multiple CBs.

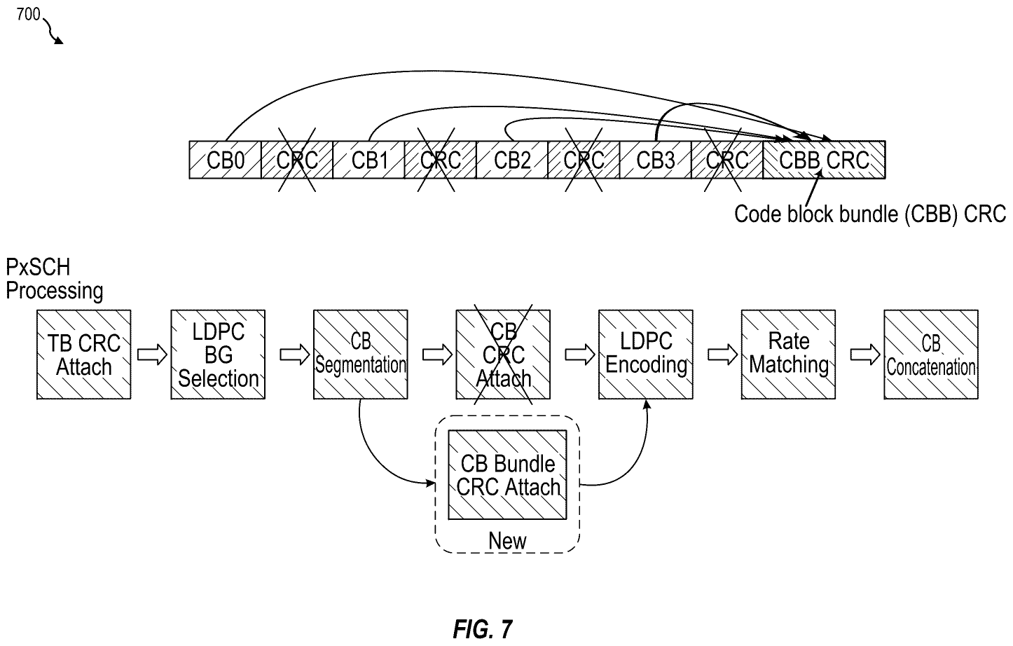

For example, as illustrated in a diagram 700 of FIG. 7, the CB bundle includes four CBs (e.g., a CB0, a CB1, a CB2, and a CB3). The transmitter node appends one or more CRC bits at the end of the CB bundle (i.e., after all the CBs or a last CB of the CB bundle, instead of appending CRC bits at the end of each individual CB of the CB bundle). For example, the transmitter node may append a CB bundle CRC at the end of the CB bundle. The CB bundle CRC may include the one or more CRC bits.

In certain aspects, all CBs of the CB bundle may be associated with a same or similar channel variation in a frequency domain.

In certain aspects, at least some CBs of the CB bundle may be associated with the same or similar channel variation in the frequency domain.

In certain aspects, a CRC length of the CB bundle CRC (e.g., the CRC length may be represented by ‘z’ and may indicate a number of the one or more CRC bits for the CB bundle CRC) may depend on a message length (e.g., of the TB), a type of an error (e.g., a burst error, a non-burst error), a length of the burst error, a bit error rate, a choice of a generator polynomial, and/or a hamming distance.

In one aspect, any CRC polynomial with the hamming distance (e.g., which may be represented by ‘d’) may detect any combination of errors (e.g., up to d-1 bit flips).

In another aspect, any CRC polynomial of a degree (e.g., the CRC length of ‘n’ bits) may detect any burst errors consisting of up to ‘n’ number of bit flips. For errors more than the ‘n’ number of bit flips, a false positive probability (e.g., a CRC of two sets of codewords being same) may be equal to

$$\frac{1}{{2}^{n}} .$$

In certain aspects, burst error patterns may not depend on a length of message bits (e.g., of the TB) for which error has to be detected. Furthermore, a false positive rate of a CRC may be a function of the CRC length (e.g., a degree of the generator polynomial) and not the length of message bits, even though a number of total bit errors may increase with the length of message. So, a CRC24 generator polynomial may be reused for the CB bundle CRC.

In certain aspects, when there are ‘n’ number of CBs in the CB bundle, then CRC savings per CB bundle (i.e., a number of CRC bits that are not used per CB bundle) may be equal to (n*24−z) bits. Therefore, there may be more CRC savings per CB bundle when there are more number of CBs in the CB bundle. In addition, when there is a large value of the number of CBs in the CB bundle, channel and/or signal-to-interference-plus-noise ratio (SINR) conditions may have higher spread across the CBs of the CB bundle, which may reduce effectiveness of the CB bundle CRC. In some cases, a value of the number of CBs in the CB bundle may be restricted by the receiver node (e.g., a UE) buffer and/or some delay constraints.

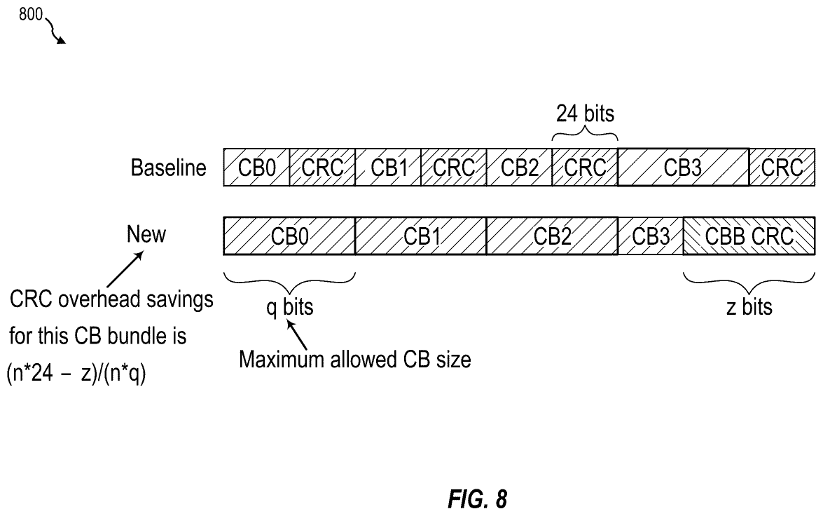

In certain aspects, a maximum allowed CB size (e.g., in bits) of a CB of the CB bundle may be represented by ‘q.’ In one example, the maximum allowed CB size of the CB may be equal to 8448 bits. In another example, the maximum allowed CB size of the CB may be equal to 3840 bits. A diagram 800 of FIG. 8 illustrates the maximum allowed CB size of one or more CBs (e.g., CB0) of the CB bundle. In this example, the maximum allowed CB size of the CB0 is equal to a number of bits for a CB as well as a number of CRC bits for the CB in some baseline systems.

In certain aspects, a number of the CB bundles for the TB (e.g., which may be represented by ‘M’) may be based on at least the maximum allowed CB size and a number of CBs in the TB. For example, the number of the CB bundles for the TB may be equal to [(TBS+TB_CRC)/(q*(n−1)+q−z)], where the TBS represents a size of the TB, the TB_CRC represents a TB CRC length (e.g., in bits), ‘q’ is the maximum allowed CB size of the CB, ‘n’ is a nominal CB bundle size indicating a number of CBs in the CB bundle (e.g., which may be a function of UE capability), and ‘z’ is the CRC length of the CB bundle CRC.

In certain aspects, the transmitter node may compute a length of the CB bundle CRC for the CB bundle based on all information bits of the CBs in the CB bundle. The transmitter node may append the CB bundle CRC at the end of the CB bundle.

In certain aspects, there may only be a single CB bundle for the TB. In such cases, the transmitter node may determine not to append the CB bundle CRC at the end of the single CB bundle. For example, no CB bundle CRC may be attached to the CB bundle when there is one CB bundle per TB. In some aspects, an integrity check of CB bundle bits may be offloaded to a TB CRC, which may perform a final check during a physical uplink shared channel (PUSCH) and/or a physical downlink shared channel (PDSCH) processing at the receiver node.

Referring back to FIG. 6, as indicated at 620, the transmitter node transmits the CB bundle to the receiver node. The receiver node may receive and process the CB bundle.

In certain aspects, instead of replacing a CB CRC altogether (i.e., not appending CRC bits at the end of individual CBs of the CB bundle), the CB CRC with a smaller CRC length (e.g., smaller than 24 bits) may be used at the end of the individual CBs of the CB bundle. A number of saved CRC bits (e.g., the CRC bits that are not used at the end of the individual CBs of the CB bundle) may be reused for constructing the CB bundle CRC at the end of the CB bundle.

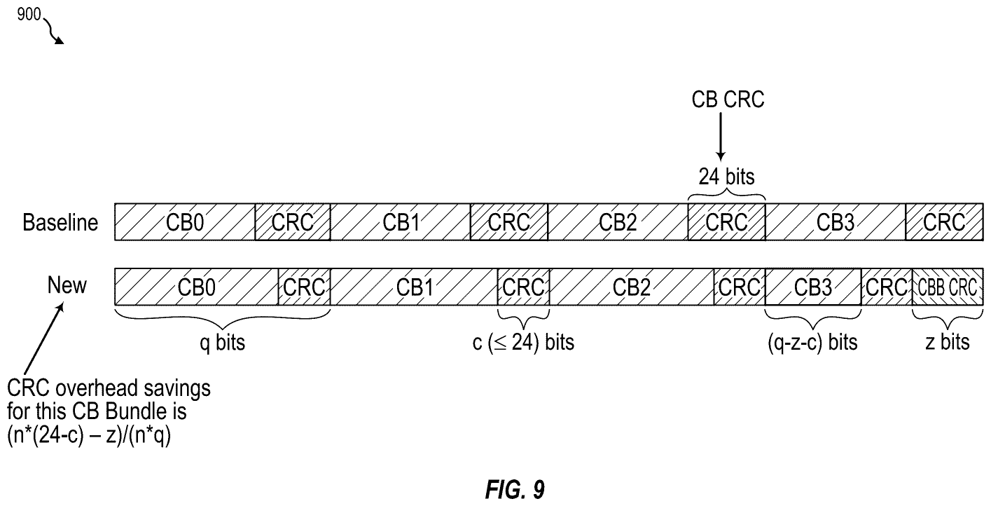

For example, as illustrated in a diagram 900 of FIG. 9, the transmitter node may append (e.g., for the PUSCH and/or PDSCH processing) a fewer number of CRC bits (e.g., ‘c’ number of bits per CB that is less than or equal to 24 CRC bits used in some baseline systems) at the end of one or more CBs (e.g., CB0, CB1, CB2) of a CB bundle (e.g., with four CBs). The transmitter node may use additional bits (e.g., ‘z’ number of CRC bits) for the CB bundle CRC at the end of individual CB bundle. The transmitter node may also append a certain number of bits (e.g., q-z-c number of bits) at the end of at least a last CB (e.g., CB3) of the CB bundle, where ‘q’ may indicate a total number of bits for a certain CB (e.g., CB0) and CRC bits appended to the CB0. In this example, CRC overhead savings for the CB bundle may be equal to (n*(24-c)−z)/(n*q) number of bits.

In certain aspects, the transmitter node (e.g., such as the UE) may maintain a same CRC length across CBs of the CB bundle for simpler UE implementation. The transmitter node may also have an option to perform additional CB-level checks to find erroneous CBs within the CB bundle.

In certain aspects, the CB bundle that may include highly correlated CBs may require a smaller value of ‘c’ for error detection of individual CBs in the CB bundle. That is, the CBs in the CB bundle experiencing almost similar channels may not need sophisticated and long CRC attached to them since the CB bundle CRC at the end of the CB bundle is sufficient.

In certain aspects, a gNodeB (gNB) may define a reduced CRC length per CB from a baseline CRC polynomial set (e.g., including a first CRC length (CRC16), a second CRC length (CRC11), and a third CRC length (CRC6)). The transmitter node may use the first CRC length, the second CRC length, or the third CRC length for the CB CRC.

In certain aspects, the gNB may define a fixed value of ‘c’ for all delay spreads.

In certain aspects, the gNB may define a value of ‘c’ based on an estimated value of a delay spread. For example, the gNB may define the first CRC length for the CB CRC when a delay spread value is less than a first delay spread threshold. The gNB may define the second CRC length for the CB CRC when the delay spread value is more than the first delay spread threshold but is less than a second delay spread threshold. The gNB may define the third CRC length for the CB CRC when the delay spread value is more than the second delay spread threshold. A value of the first delay spread threshold is different from a value of the second delay spread threshold.

In certain aspects, the first delay spread threshold and the second delay spread threshold are predefined delay thresholds based on a numerology and a CB interleaving granularity (e.g., K tones and/or bits). The UE and/or the gNB may be aware of the first delay spread threshold and/or the second delay spread threshold.

In certain aspects, the transmitter node may determine to replace the CB CRC altogether (i.e., not appending CRC bits at the end of individual CBs of the CB bundle) or use the CB CRC with a smaller CRC length at the end of the individual CBs of the CB bundle, based on a degree of interleaving across the CBs of the CB bundle. For example, when an interleaving unit (e.g., resource elements or bits), the delay spread and/or a sub carrier spacing is smaller, a degree of correlation among channels seen by the CBs of the CB bundle may be larger and the transmitter node may append only CB bundle level CRC instead of CB level CRC bits.

In certain aspects, when the channels seen by the CBs of the CB bundle may not be highly correlated (e.g., at a low signal to noise ratio, where a CB block error rate is high), then an assumption of all-or-none in the CB bundle error detection may fail (i.e., the CB bundle CRC may fail while CRC checks may pass for some of the CBs of the CB bundle). In such cases, the transmitter node may use the CB CRC with a smaller CRC length at the end of the individual CBs of the CB bundle, as this may help avoid retransmissions of the CBs provided CB-level acknowledgment support is available.

### Example Methods for Wireless Communications

FIG. 10 shows an example of a method 1000 for wireless communications at a transmitter node. In one example, the transmitter node may be a user equipment (UE), such as the UE 104 of FIG. 1 and FIG. 3. In another example, the transmitter node may be a network entity, such as the BS 102 depicted and described with respect to FIG. 1 and FIG. 3, or the disaggregated BS depicted and described with respect to FIG. 2.

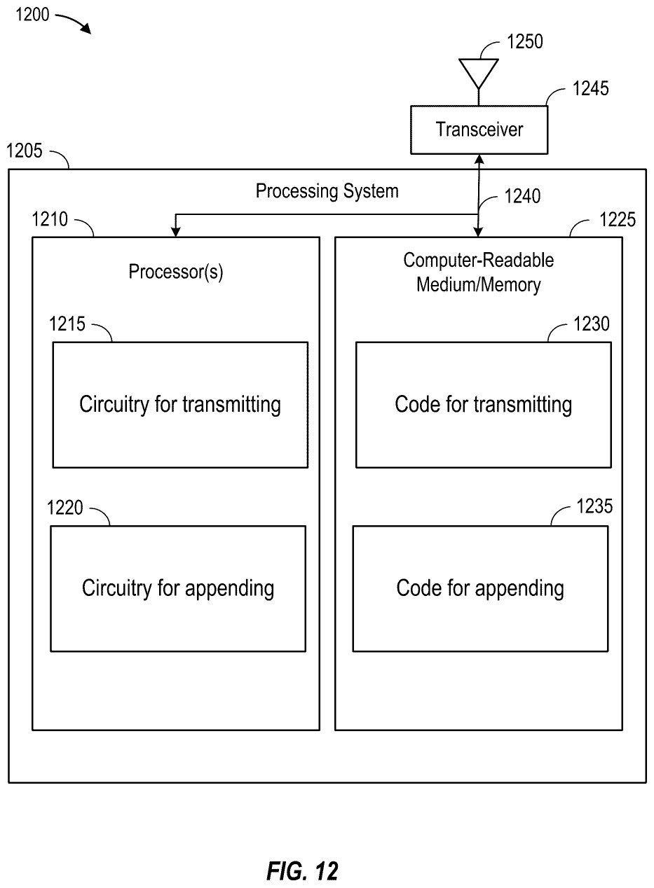

Method 1000 begins at 1010 with appending one or more cyclic redundancy check (CRC) bits at an end of one or more code block (CB) bundles. Each of the one or more CB bundles includes a plurality of CBs. In some cases, the operations of this step refer to, or may be performed by, circuitry for appending and/or code for appending as described with reference to FIG. 12.

Method 1000 then proceeds to 1020 with transmitting at least one of the one or more CB bundles. In some cases, the operations of this step refer to, or may be performed by, circuitry for transmitting and/or code for transmitting as described with reference to FIG. 12.

In certain aspects, all of the plurality of CBs in the at least one of the one or more CB bundles are associated with a similar channel variation in a frequency domain.

In certain aspects, a quantity of the one or more CB bundles is based on a maximum allowable size of a CB and a quantity of CBs.

In certain aspects, the method 1000 further includes computing a CB bundle CRC for the at least one of the one or more CB bundles based on all information bits of the plurality of CBs in the at least one of the one or more CB bundles. The CB bundle CRC includes at least the one or more CRC bits. The appending includes appending the CB bundle CRC at an end of the at least one of the one or more CB bundles.

In certain aspects, the method 1000 further includes determining that a quantity of the one or more CB bundles for a transport block (TB) is equal to one, and determining not to append a CB bundle CRC including at least the one or more CRC bits at an end of a single CB bundle when the quantity of the one or more CB bundles for the TB is equal to one.

In one aspect, the method 1000, or any aspect related to it, may be performed by an apparatus, such as a communications device 1200 of FIG. 12, which includes various components operable, configured, or adapted to perform the method 1000. The communications device 1200 is described below in further detail.

Note that FIG. 10 is just one example of a method, and other methods including fewer, additional, or alternative steps are possible consistent with this disclosure.

FIG. 11 shows an example of a method 1100 for wireless communications at a transmitter node. In one example, the transmitter node may be a UE, such as the UE 104 of FIG. 1 and FIG. 3. In another example, the transmitter node may be a network entity, such as the BS 102 depicted and described with respect to FIG. 1 and FIG. 3, or the disaggregated BS depicted and described with respect to FIG. 2.

Method 1100 begins at 1110 with appending a first quantity of CRC bits at an end of at least one CB of a CB bundle including a plurality of CBs. The first quantity of CRC bits is less than a second quantity of CRC bits configured for the at least one CB of the CB bundle. In some cases, the operations of this step refer to, or may be performed by, circuitry for appending and/or code for appending as described with reference to FIG. 12.

Method 1100 then proceeds to 1120 with transmitting the CB bundle. In some cases, the operations of this step refer to, or may be performed by, circuitry for transmitting and/or code for transmitting as described with reference to FIG. 12.

In certain aspects, the second quantity of CRC bits is based on a maximum allowable quantity of CRC bits for the at least one CB of the CB bundle.

In certain aspects, the method 1100 further includes determining a third quantity of CRC bits for the at least one CB of the CB bundle based on a difference between the second quantity of CRC bits configured for the at least one CB of the CB bundle and the first quantity of CRC bits for the at least one CB of the CB bundle. The appending further includes appending a CB bundle CRC including the third quantity of CRC bits for the at least one CB of the CB bundle at an end of the at least one CB of the CB bundle.

In certain aspects, a CRC length for each of the plurality of CBs of the CB bundle is same.

In certain aspects, a same CRC length for each of the plurality of CBs of the CB bundle is defined for all values of a delay spread.

In certain aspects, a CRC length for each of the plurality of CBs of the CB bundle depends on a value of a delay spread.

In certain aspects, a first CRC length is based on a determination of the delay spread satisfying a first value of a delay spread threshold. A second CRC length is based on a determination of the delay spread satisfying a second value of the delay spread threshold. A third CRC length is based on a determination of the delay spread satisfying a third value of the delay spread threshold. The first CRC length, the second CRC length, and the third CRC length are different from each other. The first value of the delay spread threshold, the second value of the delay spread threshold, and the third value of the delay spread threshold are different from each other.

In certain aspects, the method 1100 further includes appending a CB bundle CRC with one of the first CRC length, the second CRC length or the third CRC length at an end of the at least one CB of the CB bundle.

In one aspect, the method 1100, or any aspect related to it, may be performed by an apparatus, such as a communications device 1200 of FIG. 12, which includes various components operable, configured, or adapted to perform the method 1100. The communications device 1200 is described below in further detail.

Note that FIG. 11 is just one example of a method, and other methods including fewer, additional, or alternative steps are possible consistent with this disclosure.

### Example Communications Device

FIG. 12 depicts aspects of an example communications device 1200. For example, the communications device 1200 may be a transmitter node such as a user equipment (UE) (e.g., the UE 104 of FIG. 1 and FIG. 3). In another example, the communications device 1200 may be a network entity, such as the BS 102 depicted and described with respect to FIG. 1 and FIG. 3, or the disaggregated BS depicted and described with respect to FIG. 2.

The communications device 1200 includes a processing system 1205 coupled to a transceiver 1245 (e.g., a transmitter and/or a receiver). The transceiver 1245 is configured to transmit and receive signals for the communications device 1200 via an antenna 1250, such as the various signals as described herein. The processing system 1205 may be configured to perform processing functions for the communications device 1200, including processing signals received and/or to be transmitted by the communications device 1200.

The processing system 1205 includes one or more processors 1210. In various aspects, the one or more processors 1210 may be representative of one or more of receive processor 358, transmit processor 364, TX MIMO processor 366, and/or controller/processor 380, as described with respect to FIG. 3. The one or more processors 1210 are coupled to a computer-readable medium/memory 1225 via a bus 1240. In certain aspects, the computer-readable medium/memory 1225 is configured to store instructions (e.g., computer-executable code) that when executed by the one or more processors 1210, cause the one or more processors 1210 to perform the methods 1000, 1100 described with respect to FIGS. 10-11, and/or any aspect related to it. Note that reference to a processor performing a function of communications device 1200 may include the one or more processors 1210 performing that function of communications device 1200.

In the depicted example, computer-readable medium/memory 1225 stores code (e.g., executable instructions), such as code for transmitting (or outputting) 1230, code for appending 1235, code for computing and/or code for determining. Processing of the code for transmitting (or outputting) 1230, the code for appending 1235, the code for computing and/or the code for determining may cause the communications device 1200 to perform the methods 1000, 1100 described with respect to FIGS. 10-11, and/or any aspect related to it.

The one or more processors 1210 include circuitry configured to implement (e.g., execute) the code stored in the computer-readable medium/memory 1225, including circuitry such as circuitry for transmitting (or outputting) 1215, circuitry for appending 1220, circuitry for computing and/or circuitry for determining. Processing with the circuitry for transmitting (or outputting) 1215, the circuitry for appending 1220, the circuitry for computing and/or the circuitry for determining may cause the communications device 1200 to perform the methods 1000, 1100 described with respect to FIGS. 10-11, and/or any aspect related to it.

Various components of the communications device 1200 may provide means for performing the methods 1000, 1100 described with respect to FIGS. 10-11, and/or any aspect related to it. For example, means for transmitting, sending or outputting (e.g., for transmission) may include transceivers 354 and/or antenna(s) 352 of the UE 104 illustrated in FIG. 3 and/or the code for transmitting 1230, the circuitry for transmitting 1215, the transceiver 1245 and the antenna 1250 of the communications device 1200 in FIG. 12. Means for appending may include processors, transceivers 354 and/or antenna(s) 352 of the UE 104 illustrated in FIG. 3 and/or the code for appending 1235, the circuitry for appending 1220, the transceiver 1245 and the antenna 1250 of the communications device 1200 in FIG. 12. Means for computing may include processors, transceivers 354 and/or antenna(s) 352 of the UE 104 illustrated in FIG. 3 and/or the code for computing, the circuitry for computing, the transceiver 1245 and the antenna 1250 of the communications device 1200 in FIG. 12. Means for determining may include processors, transceivers 354 and/or antenna(s) 352 of the UE 104 illustrated in FIG. 3 and/or the code for determining, the circuitry for determining, the transceiver 1245 and the antenna 1250 of the communications device 1200 in FIG. 12.

In some cases, rather than actually transmitting, for example, signals and/or data, a device may have an interface to output signals and/or data for transmission (a means for outputting). For example, a processor may output signals and/or data, via a bus interface, to a radio frequency (RF) front end for transmission. In various aspects, an RF front end may include various components, including transmit and receive processors, transmit and receive MIMO processors, modulators, demodulators, and the like, such as depicted in the examples in FIG. 3.

In some cases, rather than actually receiving signals and/or data, a device may have an interface to obtain the signals and/or data received from another device (a means for obtaining). For example, a processor may obtain (or receive) the signals and/or data, via a bus interface, from an RF front end for reception. In various aspects, an RF front end may include various components, including transmit and receive processors, transmit and receive MIMO processors, modulators, demodulators, and the like, such as depicted in the examples in FIG. 3. Notably, FIG. 12 is an example, and many other examples and configurations of communication device 1200 are possible.

### Example Clauses

Implementation examples are described in the following numbered clauses:

Clause 1: A method for wireless communications at a transmitter node, including: appending one or more cyclic redundancy check (CRC) bits at an end of one or more code block (CB) bundles, wherein each of the one or more CB bundles includes a plurality of CBs; and transmitting at least one of the one or more CB bundles.

Clause 2: The method of clause 1, wherein all of the plurality of CBs in the at least one of the one or more CB bundles are associated with a similar channel variation in a frequency domain.

Clause 3: The method of any one of clauses 1-2, wherein a quantity of the one or more CB bundles is based on a maximum allowable size of a CB and a quantity of CBs.

Clause 4: The method of any one of clauses 1-3, further including: computing a CB bundle CRC for the at least one of the one or more CB bundles based on all information bits of the plurality of CBs in the at least one of the one or more CB bundles, wherein the CB bundle CRC includes at least the one or more CRC bits; and the appending includes appending the CB bundle CRC at an end of the at least one of the one or more CB bundles.

Clause 5: The method of any one of clauses 1-4, further including: determining that a quantity of the one or more CB bundles for a transport block (TB) is equal to one; and determining not to append a CB bundle CRC including at least the one or more CRC bits at an end of a single CB bundle when the quantity of the one or more CB bundles for the TB is equal to one.

Clause 6: A method for wireless communications at a transmitter node, including: appending a first quantity of cyclic redundancy check (CRC) bits at an end of at least one code block (CB) of a CB bundle including a plurality of CBs, wherein the first quantity of CRC bits is less than a second quantity of CRC bits configured for the at least one CB of the CB bundle; and transmitting the CB bundle.

Clause 7: The method of clause 6, wherein the second quantity of CRC bits is based on a maximum allowable quantity of CRC bits for the at least one CB of the CB bundle.

Clause 8: The method of any one of clauses 6-7, further including: determining a third quantity of CRC bits for the at least one CB of the CB bundle based on a difference between the second quantity of CRC bits configured for the at least one CB of the CB bundle and the first quantity of CRC bits for the at least one CB of the CB bundle; and the appending further includes appending a CB bundle CRC including the third quantity of CRC bits for the at least one CB of the CB bundle at an end of the at least one CB of the CB bundle.

Clause 9: The method of any one of clauses 6-8, wherein a CRC length for each of the plurality of CBs of the CB bundle is same.

Clause 10: The method of any one of clauses 6-9, further wherein a same CRC length for each of the plurality of CBs of the CB bundle is defined for all values of a delay spread.

Clause 11: The method of any one of clauses 6-10, further wherein a CRC length for each of the plurality of CBs of the CB bundle depends on a value of a delay spread.

Clause 12: The method of clause 11, wherein: a first CRC length is based on a determination of the delay spread satisfying a first value of a delay spread threshold, a second CRC length is based on a determination of the delay spread satisfying a second value of the delay spread threshold, and a third CRC length is based on a determination of the delay spread satisfying a third value of the delay spread threshold; the first CRC length, the second CRC length, and the third CRC length are different from each other; and the first value of the delay spread threshold, the second value of the delay spread threshold, and the third value of the delay spread threshold are different from each other.

Clause 13: The method of clause 12, wherein the appending further includes appending a CB bundle CRC with one of the first CRC length, the second CRC length or the third CRC length at an end of the at least one CB of the CB bundle.

Clause 14: An apparatus, comprising: at least one memory comprising instructions; and one or more processors configured, individually or in any combination, to execute the instructions and cause the apparatus to perform a method in accordance with any one of Clauses 1-13.

Clause 15: An apparatus, comprising means for performing a method in accordance with any one of Clauses 1-13.

Clause 16: A non-transitory computer-readable medium comprising executable instructions that, when executed by one or more processors of an apparatus, cause the apparatus to perform a method in accordance with any one of Clauses 1-13.

Clause 17: A computer program product embodied on a computer-readable storage medium comprising code for performing a method in accordance with any one of Clauses 1-13.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, “a processor,” “at least one processor” or “one or more processors” generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

As used herein, the term wireless node may refer to, for example, a network entity or a UE. In this context, a network entity may be a base station (e.g., a gNB) or a module (e.g., a CU, DU, and/or RU) of a disaggregated base station.

While the present disclosure may describe certain operations as being performed by one type of wireless node, the same or similar operations may also be performed by another type of wireless node. For example, operations performed by a network entity may also (or instead) be performed by a UE. Similarly, operations performed by a UE may also (or instead) be performed by a network entity.

Further, while the present disclosure may describe certain types of communications between different types of wireless nodes (e.g., between a network entity and a UE), the same or similar types of communications may occur between same types of wireless nodes (e.g., between network entities or between UEs, in a peer-to-peer scenario). Further, communications may occur in reverse order than described.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for”. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

1. An apparatus for wireless communications at a transmitter node, comprising:
at least one memory comprising instructions; and
one or more processors, individually or collectively, configured to execute the instructions and cause the apparatus to:
append one or more cyclic redundancy check (CRC) bits at an end of one or more code block (CB) bundles, wherein each of the one or more CB bundles comprises a plurality of CBs; and
transmit at least one of the one or more CB bundles.

2. The apparatus of claim 1, wherein all of the plurality of CBs in the at least one of the one or more CB bundles are associated with a similar channel variation in a frequency domain.

3. The apparatus of claim 1, wherein a quantity of the one or more CB bundles is based on a maximum allowable size of a CB and a quantity of CBs.

4. The apparatus of claim 1, wherein:
the one or more processors, individually or collectively, are configured to execute the instructions and cause the apparatus to compute a CB bundle CRC for the at least one of the one or more CB bundles based on all information bits of the plurality of CBs in the at least one of the one or more CB bundles, wherein the CB bundle CRC comprises at least the one or more CRC bits; and
the appending comprises appending the CB bundle CRC at an end of the at least one of the one or more CB bundles.

5. The apparatus of claim 1, wherein the one or more processors, individually or collectively, are configured to execute the instructions and cause the apparatus to:
determine that a quantity of the one or more CB bundles for a transport block (TB) is equal to one; and
determine not to append a CB bundle CRC comprising at least the one or more CRC bits at an end of a single CB bundle when the quantity of the one or more CB bundles for the TB is equal to one.

6. An apparatus for wireless communications at a transmitter node, comprising:
at least one memory comprising instructions; and
one or more processors, individually or collectively, configured to execute the instructions and cause the apparatus to:
append a first quantity of cyclic redundancy check (CRC) bits at an end of at least one code block (CB) of a CB bundle comprising a plurality of CBs, wherein the first quantity of CRC bits is less than a second quantity of CRC bits configured for the at least one CB of the CB bundle; and
transmit the CB bundle.

7. The apparatus of claim 6, wherein the second quantity of CRC bits is based on a maximum allowable quantity of CRC bits for the at least one CB of the CB bundle.

8. The apparatus of claim 6, wherein:
the one or more processors, individually or collectively, are configured to execute the instructions and cause the apparatus to determine a third quantity of CRC bits for the at least one CB of the CB bundle based on a difference between the second quantity of CRC bits configured for the at least one CB of the CB bundle and the first quantity of CRC bits for the at least one CB of the CB bundle; and
the appending comprises appending a CB bundle CRC comprising the third quantity of CRC bits for the at least one CB of the CB bundle at an end of the at least one CB of the CB bundle.

9. The apparatus of claim 6, wherein a CRC length for each of the plurality of CBs of the CB bundle is same.

10. The apparatus of claim 6, wherein a same CRC length for each of the plurality of CBs of the CB bundle is defined for all values of a delay spread.

11. The apparatus of claim 6, wherein a CRC length for each of the plurality of CBs of the CB bundle depends on a value of a delay spread.

12. The apparatus of claim 11, wherein:
a first CRC length is based on a determination of the delay spread satisfying a first value of a delay spread threshold, a second CRC length is based on a determination of the delay spread satisfying a second value of the delay spread threshold, and a third CRC length is based on a determination of the delay spread satisfying a third value of the delay spread threshold;
the first CRC length, the second CRC length, and the third CRC length are different from each other; and
the first value of the delay spread threshold, the second value of the delay spread threshold, and the third value of the delay spread threshold are different from each other.

13. The apparatus of claim 12, wherein the appending comprises appending a CB bundle CRC with one of the first CRC length, the second CRC length or the third CRC length at an end of the at least one CB of the CB bundle.

14. A method for wireless communications at a transmitter node, comprising:
appending a first quantity of cyclic redundancy check (CRC) bits at an end of at least one code block (CB) of a CB bundle comprising a plurality of CBs, wherein the first quantity of CRC bits is less than a second quantity of CRC bits configured for the at least one CB of the CB bundle; and
transmitting the CB bundle.

15. The method of claim 14, wherein the second quantity of CRC bits is based on a maximum allowable quantity of CRC bits for the at least one CB of the CB bundle.

16. The method of claim 14, further comprising:
determining a third quantity of CRC bits for the at least one CB of the CB bundle based on a difference between the second quantity of CRC bits configured for the at least one CB of the CB bundle and the first quantity of CRC bits for the at least one CB of the CB bundle; wherein
the appending comprises appending a CB bundle CRC comprising the third quantity of CRC bits for the at least one CB of the CB bundle at an end of the at least one CB of the CB bundle.

17. The method of claim 14, wherein a CRC length for each of the plurality of CBs of the CB bundle is same.

18. The method of claim 14, wherein a same CRC length for each of the plurality of CBs of the CB bundle is defined for all values of a delay spread.

19. The method of claim 14, wherein a CRC length for each of the plurality of CBs of the CB bundle depends on a value of a delay spread.

20. The method of claim 19, wherein:
a first CRC length is based on a determination of the delay spread satisfying a first value of a delay spread threshold, a second CRC length is based on a determination of the delay spread satisfying a second value of the delay spread threshold, and a third CRC length is based on a determination of the delay spread satisfying a third value of the delay spread threshold;
the first CRC length, the second CRC length, and the third CRC length are different from each other; and
the first value of the delay spread threshold, the second value of the delay spread threshold, and the third value of the delay spread threshold are different from each other.
